(19) United States
(12) Patent Application Publication
(10) Pub. No.: US 2026/0196251 A1
(43) Pub. Date: Jul. 9, 2026

(54) SEMICONDUCTOR DEVICE HAVING A LOCAL LINE BETWEEN CELL MATS

(71) Applicant: SK hynix Inc., Gyeonggi-do (KR)

(72) Inventor: Kyung Wan KIM, Gyeonggi-do (KR)

(21) Appl. No.: 19/218,364

(22) Filed: May 26, 2025

(30) Foreign Application Priority Data
Jan. 9, 2025 (KR) 10-2025-0003250

(51) Int. Cl. G11C 5/06

(52) U.S. Cl. CPC G11C 5/063

(57) ABSTRACT

A semiconductor device includes a cell array including a first cell MAT and a second cell MAT. The first cell MAT includes first to fourth cell tiles; a first local X-switch disposed between the first cell tile and the second cell tile; a first X-line extending the first cell tile; and a second X-line extending the second cell tile. The second cell MAT includes first to fourth cell tiles; a first local X-switch disposed between the first cell tile and the second cell tile; a first X-line extending the first cell tile; and a second X-line extending the second cell tile. The first local X-switch is electrically shared with the first X-line of the first cell MAT, the second X-line of the first cell MAT, and the first X-line of the second cell MAT. The first local X-switch of the second cell MAT is electrically shared with the second X-line of the first cell MAT, the first X-line of the second cell MAT, and the second X-line of the second cell MAT.

### CROSS-REFERENCE TO RELATED APPLICATIONS

This patent document claims priority under 35 U.S.C. 119(a) to Korean Patent Application No. 10-2025-0003250, filed on Jan. 9, 2025, which is incorporated herein by reference in its entirety.

### TECHNICAL FIELD

The present disclosure relates to a semiconductor device having cell MATs and local lines.

### BACKGROUND

A cell MAT refers to cells arranged in a matrix form in a semiconductor memory device. Each cell MAT includes a plurality of memory cells. The plurality of memory cells may be selected or enabled by turning-on local switches disposed within the cell MATs.

### SUMMARY

Embodiments of the present disclosure provide a structure and method configured to select or enable a memory cell on both sides.

Embodiments of the present disclosure provide a structure and method in which a memory cell may be selected or enabled by turning on a local switch of another adjacent cell MAT.

Embodiments of the present disclosure provide a structure and method configured to simultaneously select or enable adjacent memory cells by simultaneously turning on corresponding local switches in two adjacent cell MATs.

In accordance with an embodiment of the present disclosure, a semiconductor device includes a cell array including a first cell MAT and a second cell MAT adjacent to each other in a first direction. The first cell MAT includes first to fourth cell tiles arranged in a matrix form; a first local X-switch disposed between the first cell tile and the second cell tile; a first X-line extending from the first local X-switch to pass through the first cell tile in the first direction; and a second X-line extending from the first local X-switch to pass through the second cell tile in the first direction. The second cell MAT includes first to fourth cell tiles arranged in a matrix form; a first local X-switch disposed between the first cell tile and the second cell tile; a first X-line extending from the first local X-switch to pass through the first cell tile in the first direction; and a second X-line extending from the first local X-switch to pass through the second cell tile in the first direction. The first local X-switch of the first cell MAT is electrically shared with the first X-line of the first cell MAT, the second X-line of the first cell MAT, and the first X-line of the second cell MAT. The first local X-switch of the second cell MAT is electrically shared with the second X-line of the first cell MAT, the first X-line of the second cell MAT, and the second X-line of the second cell MAT.

In accordance with an embodiment of the present disclosure, a semiconductor device includes a cell array having first to fourth cell MATs. Each of the first to fourth cell MATs includes first to fourth cell tiles arranged in a matrix form; a first local X-switch disposed between the first cell tile and the second cell tile; a second local X-switch disposed between the third cell tile and the fourth cell tile; a first local Y-switch disposed between the first cell tile and the third cell tile; a second local Y-switch disposed between the second cell tile and the fourth cell tile; a first Y-line extending from the first local Y-switch to pass through the first cell tile; a second Y-line extending from the second local Y-switch to pass through the second cell tile; a third Y-line extending from the first local Y-switch to pass through the third cell tile; and a fourth Y-line extending from the second local X-switch to pass through the fourth cell tile. The first local Y-switch of the first cell MAT is electrically shared with the first Y-line of the first cell MAT, the third Y-line of the first cell MAT, and the first Y-line of the third cell MAT.

In accordance with an embodiment of the present disclosure, a semiconductor device includes a cell array including a first cell MAT and a second cell MAT adjacent to each other. Each of the first cell MAT and the second cell MAT includes first to fourth cell tiles arranged in a matrix form with a first direction and a second direction perpendicular to each other; a first local Y-switch disposed between the first cell tile and the third cell tile; a second local Y-switch disposed between the second cell tile and the fourth cell tile; a first Y-line extending from the second local Y-switch to pass through the first cell tile in the first direction; a second Y-line extending from the second local switch to pass through the second cell tile; a third Y-line extending from the first local Y-switch to pass through the third cell tile in the second direction; and a fourth Y-line extending from the second local switch to pass through the fourth cell tile. The first local Y-switch of the first cell MAT is electrically shared with the first Y-line of the first cell MAT, the third Y-line of the first cell MAT, and the first Y-line of the second cell MAT.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a block diagram illustrating a semiconductor device according to an embodiment of the present disclosure, and FIG. 1B is an enlarged diagram illustrating a cell MAT of FIG. 1A.

FIG. 2 is a diagram schematically illustrating a line connection structure of two cell MATs adjacent to each other in a first direction, according to an embodiment of the present disclosure.

FIG. 3 is a diagram schematically illustrating a line connection structure of two cell MATs adjacent to each other in a second direction according to an embodiment of the present disclosure.

FIG. 4 is a diagram schematically illustrating a connection structure of X-lines and Y-lines of cell MATs according to an embodiment of the present disclosure.

FIG. 5A is a block diagram of a semiconductor device according to an embodiment of the present disclosure, and FIG. 5B is a schematic enlarged diagram of cell MATs located in edge regions of the cell array of FIG. 5A.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

Throughout the specification, “be selected” and “be enabled” may mean that a current is provided or drawn. For example, “be selected” and “be enabled” can be interpreted as data being written or read.

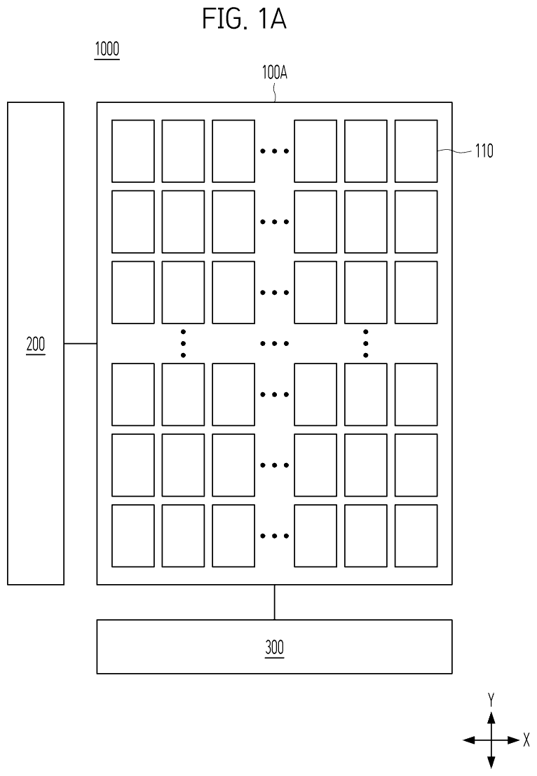

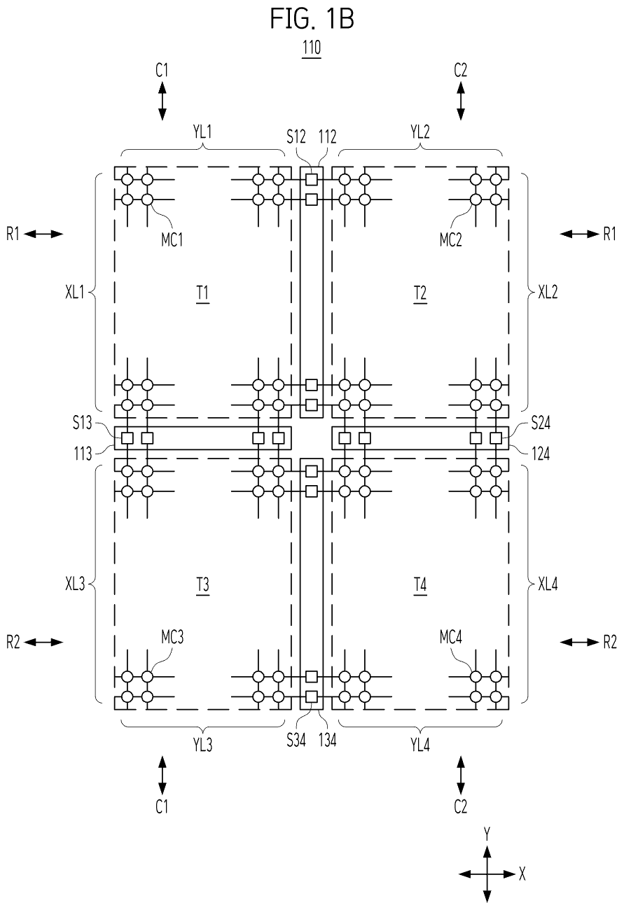

FIG. 1A is a block diagram illustrating a semiconductor device 1000 according to an embodiment of the present disclosure, and FIG. 1B is an enlarged diagram illustrating a cell MAT 110 of FIG. 1A. Referring to FIGS. 1A and 1B, the semiconductor device 1000 may include a cell array 100A, an X-decoding block 200, and a Y-decoding block 300. The cell array 100A may include a plurality of cell MATs 110 arranged in a matrix form. Each cell MAT 110 may include a plurality of memory cells MC1 to MC4 arranged in a matrix form. The X-decoding block 200 may be disposed to be electrically connected to the cell array 100A in a first direction X. The Y-decoding block 300 may be disposed to be electrically connected to the cell array 100A in a second direction Y. The first direction X may be perpendicular to the second direction Y. For example, the X-decoding block 200 may selectively enable memory cells MC1 to MC4 in the cell array 100A according to an address signal or the like. The Y-decoding block 300 may provide a voltage or current to the selected memory cells MC1 to MC4, or may read data stored in the selected memory cells MC1 to MC4. The X-decoding block 200 may include an address coding circuit, a word line driving circuit, and/or a global X-switching circuit. The Y-decoding block 300 may include a global Y-switching circuit and/or a sense amplifier circuit.

Referring to FIG. 1B, each cell MAT 110 may include cell tiles T1 to T4 and local switch blocks 112, 113, 124, and 134. The cell tiles T1-T4 may include first to fourth cell tiles T1-T4 arranged in a matrix form in the first direction X and the second direction Y. For example, the first cell tile T1 may be disposed on a top-left position (on a first (upper of top) row R1 and a first (left) column C1), the second cell tile T2 may be disposed on a top-right position (on the first row R1 and a second (right) column C2), the third cell tile T3 may be disposed on a bottom-left position (on a second (lower of bottom) row R2 and the first column C1), and the fourth cell tile T4 may be disposed on a bottom-right position (on the second row R2 and the second column C2).

Each cell MAT 110 may include first X-lines XL1, second X-lines XL2, third X-lines XL3, and fourth X-lines XL4 each extending parallel to each other in the first direction X. The first X-lines XL1 may pass through the first cell tile T1, the second X-lines XL2 may pass through the second cell tile T2, third X-lines XL3 may pass through the third cell tile T3, and fourth X-lines XL4 may pass through the fourth cell tile T4.

Each cell MAT 110 may include first Y-lines YL1, second Y-lines YL2, third Y-lines YL3, and fourth Y-lines YL4 each extending parallel to each other in the second direction Y. The first Y-lines YL1 may pass

through the first cell tile T1, the second Y-lines YL2 may pass through the second cell tile T2, the third Y-lines YL3 may pass through the third cell tile T3, and the fourth Y-lines YL4 may pass through the fourth cell tile T4.

The first cell tile T1 may include first memory cells MC1 disposed at intersections of the first X-lines XL1 and the first Y-lines YL1 in a matrix form. The second cell tile T2 may include second memory cells MC2 disposed at intersections of the second X-lines XL2 and the second Y-lines YL2 in a matrix form. The third cell tile T3 may include third memory cells MC3 disposed at intersections of the third X-lines XL3 and the third Y-lines YL3 in a matrix form. The fourth cell tile T4 may include fourth memory cells MC4 disposed at intersections of the fourth X-lines XL4 and the fourth Y-lines YL4 in a matrix form.

The local switch blocks 112, 113, 124, and 134 may include a first local X-switch block 112, a second local X-switch block 134, a first local Y-switch block 113, and a second local Y-switch block 124. The first local X-switch block 112 may be disposed between the first cell tile T1 and the second cell tile T2, and the second local X-switch block 134 may be disposed between the third cell tile T3 and the fourth cell tile T4. The first local Y-switch block 113 may be disposed between the first cell tile T1 and the third cell tile T3, and the second local Y-switch block 124 may be disposed between the second cell tile T2 and the fourth cell tile T4. That is, the first cell tile T1, the first local X-switch block 112, and the second cell tile T2 may be aligned side-by-side on the first row R1 in the first direction X. The third cell tile T3, the second local X-switch block 134, and the fourth cell tile T4 may be aligned side-by-side on the second row R2 in the first direction X. The first cell tile T1, the first local Y-switch block 113, and the third cell tile T3 may be aligned side-by-side on the first column C1 in the second direction Y. The second cell tile T2, the second local Y-switch block 124, and the fourth cell tile T4 may be aligned side-by-side on the second column C2 in the second direction Y.

The first local X-switch block 112 may include a plurality of first local X-switches S12. The first local X-switches S12 may be arranged to be aligned in the second direction Y in the first local X-switch block 112. The second local X-switch block 134 may include a plurality of second local X-switches S34. The second local X-switches S34 may be arranged to be aligned in the second direction Y in the second local X-switch block 134.

Each first local X-switch S12 may be electrically connected to the corresponding first X-line XL1 and the corresponding second X-line XL2. When each of the first local X-switches S12 is turned-on, a current may be provided onto the corresponding first X-line XL1 and the corresponding second X-line XL2, and the first memory cells MC1 in the first cell tile T1 disposed on the corresponding first X-line XL1 and the second memory cells MC2 in the corresponding second X-line XL2 may be simultaneously selected.

Each second local X-switch S34 may be electrically connected to the corresponding third X-line XL3 and the corresponding fourth X-line XL4. When each second local X-switch S34 is turned-on, a current may be provided onto the corresponding third X-line XL3 and the corresponding fourth X-line XL4, and the third memory cells MC3 in the third cell tile T3 disposed on the corresponding third X-line XL3 and the fourth memory cells MC4 in the corresponding fourth X-line XL4 may be simultaneously selected.

The first local Y-switch block 113 may include a plurality of first local Y-switches S13. The first local Y-switches S13 may be arranged in the first direction X to be aligned in the first local Y-switch block 113. The second local Y-switch block 124 may include a plurality of second local Y-switches S24. The second local Y-switches S24 may be arranged to be aligned in the first direction X in the second local Y-switch block 124.

Each first local Y-switch S13 may be electrically connected to the corresponding first Y-line YL1 and the corresponding third Y-line YL3. When each first local Y-switch S13 is turned-on, a current may be provided onto the corresponding first Y-line YL1 and the corresponding third Y-line YL3, and the first memory cells MC1 in the first cell tile T1 disposed on the corresponding first Y-line YL1 and the third memory cells MC3 in the corresponding third Y-line YL3 may be simultaneously selected.

Each second local Y-switch S24 may be electrically connected to the corresponding second Y-line YL2 and the corresponding fourth Y-line YL4. When each second local Y-switch S24 is turned-on, a current may be provided onto the corresponding second Y-line YL2 and the fourth Y-line YL4, and the second memory cells MC3 in the second cell tile T2 disposed on the corresponding second Y-line YL2 and the fourth memory cells MC4 in the corresponding fourth Y-line YL4 may be simultaneously selected.

In FIGS. 1A and 1B, the first direction X and the second direction Y may be interchanged. Therefore, a structure and function of the X-lines XL1-XL4 and the Y-lines YL1-YL4 may be interchanged.

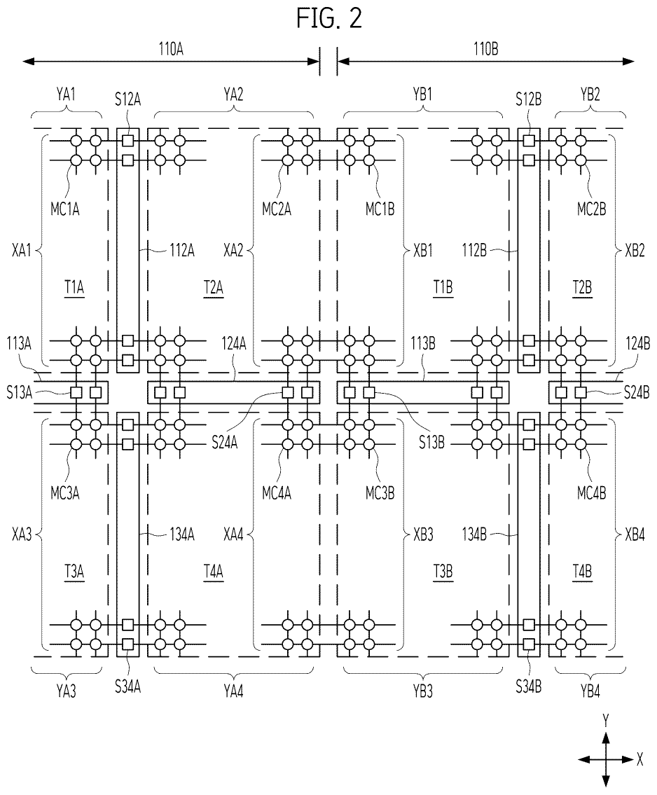

FIG. 2 is a diagram schematically illustrating a line connection structure of two cell MATs 110A and 110B adjacent to each other in the first direction X, according to an embodiment of the present disclosure.

Referring to FIG. 2, a semiconductor device according to an embodiment of the present disclosure may include a first cell MAT 110A and a second cell MAT 110B adjacent to each other in a first direction X in a cell array.

The first cell MAT 110A may include four cell tiles T1A-T4A arranged in a matrix form, local switch blocks 112A, 134A, 113A and 124A arranged between the cell tiles T1A-T4A, X-lines XA1-XA4 passing through the cell tiles T1A-T4A in the first direction X, and Y-lines YA1-YA4 passing through the cell tiles T1A-T4A in a second direction Y.

In the first cell MAT 110A, the local switch blocks 112A, 134A, 113A, and 124A may include a first local X-switch block 112A disposed between the first cell tile T1A and the second cell tile T2A in the first direction X, a second local X-switch block 134A disposed between the third cell tile T3A and the fourth cell tile T4A in the first direction X, a first local Y-switch block 113A disposed between the first cell tile T1A and the third cell tile T3A in the second direction Y, and a second local Y-switch block 124A disposed between the second cell tile T2A and the fourth cell tile T4A in the second direction Y.

In the first cell MAT 110A, the first local X-switch block 112A may include first local X-switches S12A arranged to be aligned in the second direction Y, the second local switch block 134A may include second local X-switches S34A arranged to be aligned in the second direction Y, the first local Y-switch block 113A may include first local Y-switches S13A arranged to be aligned in the first direction X, and the second local Y-switch block 124A may include second local Y-switches S24A arranged to be aligned in the first direction X.

In the first cell MAT 110A, the X-lines XA1-XA4 may include first X-lines XA1, second X-lines XA2, third X-lines XA3, and fourth X-lines XA4. The first X-lines XA1 may pass through the first cell tile T1A from the first local X-switches S12A to be electrically connected to the first memory cells MC1A. The second X-lines XA2 may pass through the second cell tile T2A from the first local X-switches S12A to be electrically connected to the second memory cells MC2A. The third X-lines XA3 may pass through the third cell tile T3A from the second local X-switches S34A to be electrically connected to the third memory cells MC3A. The fourth X-lines XA4 may pass through the fourth cell tile T4A from the second local X-switches S34A to be electrically connected to the fourth memory cells MC4A.

In the first cell MAT 110A, the Y-lines YA1-YA4 may include first Y-lines YA1, second Y-lines YA2, third Y-lines YA3, and fourth Y-lines YA4. The first Y-lines YA1 may pass through the first cell tile T1A from the first local Y-switches S13A to be electrically connected to the first memory cells MC1A. The second Y-lines YA2 may pass through the second cell tile T2A from the second local Y-switches S24A to be electrically connected to the second memory cells MC2A. The third Y-lines YA3 may pass through the third cell tile T3A from the first local X-switches S13A to be electrically connected to the third memory cells MC3A. The fourth Y-lines YA4 may pass through the fourth cell tile T4A from the second local Y-switches S24A to be electrically connected to the fourth memory cells MC4A.

The second cell MAT 110B may include four cell tiles T1B-T4B arranged in a matrix form, local switch blocks 112B, 134B, 113B, and 124B arranged between the cell tiles T1B-T4B, X-lines XB1-XB4 passing through the cell tiles T1B-T4B in the first direction X, and Y-lines YB1-YB4 passing through the cell tiles T1B-T4B in the second direction Y.

In the second cell MAT 110B, the local switch blocks 112B, 134B, 113B, and 124B may include a first local X-switch block 112B disposed between the first cell tile T1B and the second cell tile T2B in the first direction X, a second local X-switch block 134B disposed between the third cell tile T3B and the fourth cell tile T4B in the first direction X, a first local Y-switch block 113B disposed between the first cell tile T1B and the third cell tile T3B in the second direction Y, and second local Y-switch block 124B disposed between the second cell tile T2B and the fourth cell tile T4B in the second direction Y.

In the second cell MAT 110B, the first local X-switch block 112B may include first local X-switches S12B arranged to be aligned in the second direction Y, the second local switch block 134B may include second local X-switches S34B arranged to be aligned in the second direction Y-the first local Y-switch block 113B may include first local Y-switches S13B arranged to be aligned in the first direction X, and the second local Y-switch block 124B may include second local Y-switches S24B arranged to be aligned in the first direction X.

In the second cell MAT 110B, the X-lines XB1-XB4 may include first X-lines XB1, second X-lines XB2, third X-lines XB3, and fourth X-lines XB4. The first X-lines XB1 may pass through the first cell tile T1B from the first local X-switches S12B to be electrically connected to the first memory cells MC1B. The second X-lines XB2 may pass through the second cell tile T2B from the first local X-switches S12B to be electrically connected to the second memory cells MC2B. The third X-lines XB3 may pass through the third cell tile T3B from the second local X-switches S34B to be electrically connected to the third memory cells MC3B. The fourth X-lines XB4 may pass through the fourth cell tile T4B from the second local X-switches S34B to be electrically connected to the fourth memory cells MC4B.

In the second cell MAT 110B, the Y-lines YB1-YB4 may include first Y-lines YB1, second Y-lines YB2, third Y-lines YB3, and fourth Y-lines YB4. The first Y-lines YB1 may pass through the first cell tile T1B from the first local Y-switches S13B to be electrically connected to the first memory cells MC1A. The second Y-lines YB2 may pass through the second cell tile T2B from the second local Y-switches S24B to be electrically connected to the second memory cells MC2B. The third Y-lines YB3 may pass through the third cell tile T3B from the first local X-switches S13B. The fourth Y-lines YB4 may pass through the fourth cell tile T4B from the second local Y-switches S24B to be electrically connected to the fourth memory cells MC4B.

In the first direction X, the X-lines XA2 passing through the second cell tile T2A of the first cell MAT 110A and the X-lines XB1 passing through the first cell tile T1B of the second cell MAT 110B may be electrically connected to each other, respectively. In the first direction X, the X-lines XA4 passing through the fourth cell tile T4A of the first cell MAT 110A and the X-lines XB3 passing through the third cell tile T3B of the second cell MAT 110B may be electrically connected to each other, respectively.

When the corresponding first local X-switch S12A of the first cell MAT 110A is turned on, the corresponding memory cells MC1A in the first cell tile T1A of the first cell MAT 110A electrically connected through the corresponding X-line XA1, the corresponding memory cells MC2A in the second cell tile T2A of the first cell MAT 110A electrically connected through the corresponding X-line XA2, and the corresponding memory cells MC1B in the first cell tile T1B of the second cell MAT 110B electrically connected to the corresponding X-line XB1 may be simultaneously selected and enabled. The first memory cells MC1A in the first cell tile T1A of the first cell MAT 110A, the second memory cells MC2A in the second cell tile T2A of the first cell MAT 110A, and the first memory cells MC1B in the first cell tile T1B of the second cell MAT 110B may receive a current from the first local X-switches S12A of the first cell MAT 110A. The first memory cells MC1A in the first cell tile T1A of the first cell MAT 110A, the second memory cells MC2A in the second cell tile T2A of the first cell MAT 110A, and the first memory cells MC1B in the first cell tile T1B of the second cell MAT 110B may electrically share the first local X-switches S12A of the first cell MAT 110A. For example, the first local X-switches S12A of the first cell MAT 110A may be electrically shared with first X-line XA1 of the first cell MAT 110A, the second X-line XA2 of the first cell MAT 110A, and the first X-line XB1 of the second cell MAT 110B.

When the first local X-switch S12B of the second cell MAT 110B is turned on, the corresponding memory cells MC2A in the second cell tile T2A of the first cell MAT 110A electrically connected through the corresponding X-line XA2, the corresponding memory cells MC1B in the first cell tile T1B of the second cell MAT 110B electrically connected through the corresponding X-line XB1, and the corresponding memory cells MC2B in the second cell tile T2B of the second cell MAT 110B electrically connected through the corresponding X-line XB2 may be simultaneously selected and enabled. The second memory cells MC2A in the second cell tile T2A of the first cell MAT 110A, the first memory cells MC1B in the first cell tile T1B of the second cell MAT 110B, and the second memory cells MC2B in the second cell tile T2B of the second cell MAT 110B may receive current from the first local X-switches S12B of the second cell MAT 110B. The second memory cells MC2A in the second cell tile T2A of the first cell MAT 110A, the first memory cells MC1B in the first cell tile T1B of the second cell MAT 110B, and the second memory cells MC2B in the second cell tile T2B of the second cell MAT 110B may electrically share the first local X-switches S12B of the second cell MAT 110B. For example, the first local X-switches S12A of the second cell MAT 110B may be electrically shared with the second X-line XA2 of the first cell MAT 110A, the first X-line XB1 of the second cell MAT 110B, and the second X-line XB2 of the second cell MAT 110B.

When the corresponding first local X-switch S12A of the first cell MAT 110A and the corresponding second local X-switch S12B of the second cell MAT 110B electrically connected through the corresponding X-lines XA2 and XB1 are simultaneously turned on, the corresponding memory cells MC1A MC2A, MC1B, and MC2B electrically connected through the corresponding X-lines XA1, XA2, XB1, and XB2 may be simultaneously selected and enabled.

When the corresponding second local X-switch S34A of the first cell MAT 110A is turned on, the corresponding memory cells MC3A in the third cell tile T3A of the first cell MAT 110A electrically connected through the corresponding X-line XA3, the corresponding memory cells MC4A in the fourth cell tile T4A of the first cell MAT 110A electrically connected through the corresponding X-line XA4, and the corresponding memory cells MC3B in the third cell tile T3B of the second cell MAT 110B electrically connected to the corresponding X-line XB3 may be simultaneously selected and enabled. The third memory cells MC3A in the third cell tile T3A of the first cell MAT 110A, the fourth memory cells MC4A in the fourth cell tile T4A of the first cell MAT 110A, and the third memory cells MC3B in the third cell tile T3B of the second cell MAT 110B may receive current from the second local X-switches S34A of the first cell MAT 110A. The third memory cells MC3A in the third cell tile T3A of the first cell MAT 110A, the fourth memory cells MC4A in the fourth cell tile T4A of the first cell MAT 110A, and the third memory cells MC3B in the third cell tile T3B of the second cell MAT 110B may electrically share the second local X-switches S34A of the first cell MAT 110A.

When the corresponding second local X-switch S34B of the second cell MAT 110B is turned on, the corresponding memory cells MC4A in the fourth cell tile T4A of the first cell MAT 110A electrically connected through the corresponding X-line XA4, the corresponding memory cells MC3B in the third cell tile T3B of the second cell MAT 110B electrically connected through the corresponding X-line XB3, and the corresponding memory cells MC4B in the fourth cell tile T4B of the fourth cell MAT 110B electrically connected through the corresponding X-line XB4 may be simultaneously selected and enabled.

When the corresponding second local X-switch S34A of the first cell MAT 110A and the corresponding second local X-switch S34B of the second cell MAT 110B electrically connected through corresponding the X-lines XA4 and XB3 are simultaneously turned on, the corresponding memory cells MC3A MC4A, MC3B, and MC4B electrically connected through the corresponding X-lines XA3, XA4, XB3, and XB4 may all be simultaneously selected and enabled. The fourth memory cells MC4A in the fourth cell tile T4A of the first cell MAT 110A, the third memory cells MC3B in the third cell tile T3B of the second cell MAT 110B, and the fourth memory cells MC4B in the fourth cell tile T4B of the second cell MAT 110B may receive current from the second local X-switches S34B of the second cell MAT 110B. The fourth memory cells MC4A in the fourth cell tile T4A of the first cell MAT 110A, the third memory cells MC3B in the third cell tile T3B of the second cell MAT 110B, and the fourth memory cells MC4B in the fourth cell tile T4B of the second cell MAT 110B may electrically share the second local X-switches S34B of the second cell MAT 110B.

The memory cells MC2A, MC1B, MC4A, and MC3B in the cell tiles T2A, T1B, T4A, and T3B disposed to be adjacent to boundary regions (or edge regions) of the first cell MAT 110A and the second cell MAT 110B may simultaneously receive current from both switches S12A, S12B, S34A, and S34B. Therefore, in each of the cell tiles T2A, T1B, T4A, and T3B, the memory cells MC2A, MC1B, MC4A, and MC3B located far from both switches S12A, S34A, S12B and S34B can receive sufficient current, can be stably selected, and can operate.

The local Y-switch blocks S13A, S24A, S13B, and S24B and the Y-lines YA13, YA24, YB13, and YB24 may be understood with reference to FIG. 1B.

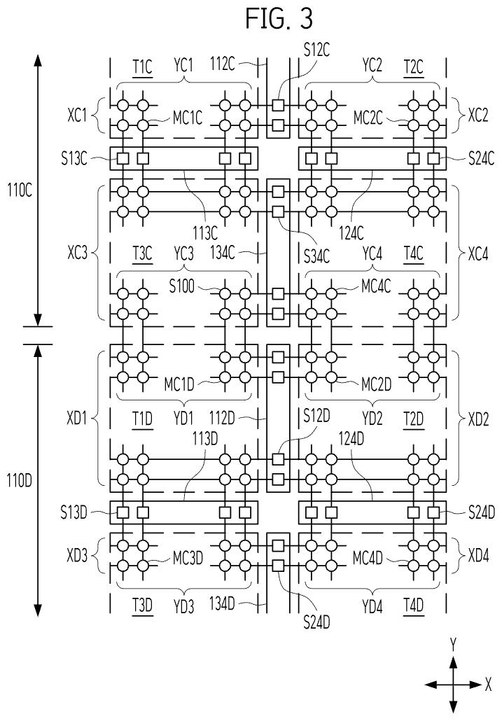

FIG. 3 is a diagram schematically illustrating a line connection structure of two cell MATs 110C and 110D adjacent to each other in the second direction Y according to an embodiment of the present disclosure.

Referring to FIG. 3, a semiconductor device according to an embodiment of the present disclosure may include cell MATs 110C and 110D adjacent to each other in the second direction Y in a cell array.

The first cell MAT 110C may include four cell tiles T1C-T4C arranged in a matrix form, local switch blocks 112C, 134C, 113C, and 124C arranged between the cell tiles T1C-T4C, X-lines XC1-XC4 passing through the cell tiles T1C in the first direction X, and Y-lines YC1-YC4 passing through the cell tiles T1C-T4C in the second direction Y.

In the first cell MAT 110C, the local switch blocks 112C, 134C, 113C, and 124C may include a first local X-switch block 112C disposed between the first cell tile T1C and the second cell tile T2C in the first direction X, a second local X-switch block 134C disposed between the third cell tile T3C and the fourth cell tile T4C in the first direction X, a first local Y-switch block 113C disposed between the first cell tile T1C and the third cell tile T3C in the second direction Y, and a second local Y-switch block 124C disposed between the second cell tile T2C and the fourth cell tile T4C in the second direction Y.

In the first cell MAT 110C, the first local X-switch block 112C may include first local X-switches S12C arranged to be aligned in the second direction Y, the second local switch block 134C may include second local X-switches S34C arranged to be aligned in the second direction Y, the first local Y-switch block 113C may include first local Y-switches S13C arranged to be aligned in the first direction X, and the second local Y-switch block 124C may include second local Y-switches S24C arranged to be aligned in the first direction X.

In the first cell MAT 110C, the X-lines XC1-XC4 may include first X-lines XC1, second X-lines XC2, third X-lines XC3, and fourth X-lines XC4. The first X-lines XC1 may pass through the first cell tile T1C from the first local X-switches S12C to be electrically connected to the first memory cells MC1C. The second X-lines XC2 may pass through the second cell tile T2C from the first local X-switches S12C to be electrically connected to the second memory cells MC2C. The third X-lines XC3 may pass through the third cell tile T3C from the second local X-switches S34C to be electrically connected to the third memory cells MC3C. The fourth X-lines XC4 may pass through the fourth cell tile T4C from the second local X-switches S34C and are electrically connected to the fourth memory cells MC4C.

In the first cell MAT 110C, the Y-lines YC1-YC4 may include first Y-lines YC1, second Y-lines YC2, third Y-lines YC3, and fourth Y-lines YC4. The first Y-lines YC1 may pass through the first cell tile T1C from the first local Y-switches S13C to be electrically connected to the first memory cells MC1C. The second Y-lines YC2 may pass through the second cell tile T2C from the second local Y-switches S24C to be electrically connected to the second memory cells MC2C. The third Y-lines YC3 may pass through the third cell tile T3C from the first local Y-switches S13C to be electrically connected to the third memory cells MC3C. The fourth Y-lines YC4 may pass through the fourth cell tile T4C from the second local Y-switches S24C and are electrically connected to the fourth memory cells MC4C.

The second cell MAT 110D may include four cell tiles T1D-T4D arranged in a matrix form, local switch blocks 112D, 134D, 113D, and 124D arranged between the cell tiles T1D-T4D, X-lines XD1-XD4 passing through the cell tiles T1D in the first direction X, and Y-lines YD1-YD4 passing through the cell tiles T1D-T4D in the second direction Y.

In the second cell MAT 110D, the local switch blocks 112D, 134D, 113D, and 124D may include a first local X-switch block 112D disposed between the first cell tile T1D and the second cell tile T2D in the first direction X, a second local X-switch block 134D disposed between the third cell tile T3D and the fourth cell tile T4D in the first direction X, and a first local Y-switch block 113D disposed between the first cell tile T1D and the third cell tile T3D in the second direction Y, and a second local Y-switch block 124D disposed between the second cell tile T2D and the fourth cell tile T4D in the second direction Y.

In the second cell MAT 110D, the first local X-switch block 112D may include first local X-switches S12D arranged to be aligned in the second direction Y, the second local X-switch block 134D may include second local X-switches S34D arranged to be aligned in the second direction Y, the first local Y-switch block 113D may include first local Y-switches S13D arranged to be aligned in the first direction X, and the second local Y-switch block 124D may include second local Y-switches S24D arranged to be aligned in the first direction X.

In the second cell MAT 110D, the X-lines XD1-XD4 may include first X-lines XD1, second X-lines XD2, third X-lines XD3, and fourth X-lines XD4. The first X-lines XD1 may pass through the first cell tile T1D from the first local X-switches S12D and are electrically connected to the first memory cells MC1D. The second X-lines XD2 may pass through the second cell tile T2D from the first local X-switches S12D to be electrically connected to the second memory cells MC2D. The third X-lines XD3 may pass through the third cell tile T3D from the second local X-switches S12D to be electrically connected to the third memory cells MC3D. The fourth X-lines XD4 may pass through the fourth cell tile T4D from the second local X-switches S34D to be electrically connected to the fourth memory cells MC4D.

In the second cell MAT 110D, the Y-lines YD1-YD4 may include first Y-lines YD1, second Y-lines YD2, third Y-lines YD3, and fourth Y-lines YD4. The first Y-lines YD1 may pass through the first cell tile T1D from the first local Y-switches S13D to be electrically connected to the first memory cells MC1D. The second Y-lines YD2 may pass through the second cell tile T2D from the second local Y-switches S24D to be electrically connected to the second memory cells MC2D. The third Y-lines YD3 may pass through the third cell tile T3D from the first local X-switches S13D to be electrically connected to the third memory cells MC3D. The fourth Y-lines YD4 may pass through the fourth cell tile T4D from the second local Y-switches S24D to be electrically connected to the fourth memory cells MC4D.

In the second direction Y, the Y-lines YC3 passing through the third cell tile T3C of the first cell MAT 110C and the Y-lines YD3 passing through the first cell tile T1D of the second cell MAT 110D may be electrically connected to each other, respectively. In the second direction Y, the Y-lines YC4 passing through the fourth cell tile T4C of the first cell MAT 110C and the Y-lines YD4 passing through the second cell tile T2D of the second cell MAT 110D may be electrically connected to each other, respectively.

When the corresponding first local Y-switch S13C of the first cell MAT 110C is turned on, the corresponding memory cells MC1C in the first cell tile T1C of the first cell MAT 110C electrically connected through the corresponding Y-line YC1, the corresponding memory cells MC3C in the third cell tile T3C of the first cell MAT 110C electrically connected through the corresponding Y-line YC3, and the corresponding memory cells MC1D in the first cell tile T1D of the second cell MAT 110D electrically connected to the corresponding Y-line YD1 may be simultaneously selected and enabled. The first memory cells MC1C in the first cell tile T1C of the first cell MAT 110C, the third memory cells MC3C in the third cell tile T3C of the first cell MAT 110C, and the first memory cells MC1D in the first cell tile T1D of the second cell MAT 110D may receive a current from the first local Y-switches S13C of the first cell MAT 110C. The first memory cells MC1C in the first cell tile T1C of the first cell MAT 110C, the third memory cells MC3C in the third cell tile T3C of the first cell MAT 110C, and the first memory cells MC1D in the first cell tile T1D of the second cell MAT 110D may electrically share the first local Y-switches S13C of the first cell MAT 110C.

When the first local X-switch S12D of the second cell MAT 110D is turned on, the corresponding memory cells MC3C in the third cell tile T3C of the first cell MAT 110C electrically connected through the corresponding Y-line YC3, the corresponding memory cells MC1D in the first cell tile T1D of the second cell MAT 110D electrically connected through the corresponding Y-line YD1, and the corresponding memory cells MC3D in the third cell tile T3D of the second cell MAT 110D electrically connected through the corresponding Y-line YD3 may be simultaneously selected and enabled. The third memory cells MC3C in the third cell tile T3C of the first cell MAT 110C, the first memory cells MC1D in the first cell tile T1D of the second cell MAT 110D, and the third memory cells MC3D in the third cell tile T3D of the second cell MAT 110D may receive a current from the first local Y-switches S13D of the second cell MAT 110D. The third memory cells MC3C in the third cell tile T3C of the first cell MAT 110C, the first memory cells MC1D in the first cell tile T1D of the second cell MAT 110D, and the third memory cells MC3D in the third cell tile T3D of the second cell MAT 110D may electrically share the first local Y-switches S13D of the second cell MAT 110D.

When the corresponding first local Y-switch S13C of the first cell MAT 110D and the corresponding first local X-switch S13D of the second cell MAT 110D electrically connected through the corresponding Y-lines YC3 and YD1 are simultaneously turned on, the corresponding memory cells MC1C MC3C, MC1D, and MC3D electrically connected through the corresponding Y-lines YC1, YC3, YD1, and YD3 may all be simultaneously selected and enabled.

When the corresponding second local Y-switch S24C of the first cell MAT 110C is turned on, the corresponding memory cells MC2C in the second cell tile T2C of the first cell MAT 110C electrically connected through the corresponding Y-line YC2, the corresponding memory cells MC4C in the fourth cell tile T4C of the first cell MAT 110C electrically connected through the corresponding Y-line YC4, and the corresponding memory cells MC2D in the second cell tile T2D of the second cell MAT 110D electrically connected to the corresponding Y-line YD2 may be simultaneously selected and enabled. The second memory cells MC2C in the second cell tile T2C of the first cell MAT 110C, the fourth memory cells MC4C in the fourth cell tile T4C of the first cell MAT 110C, and the second memory cells MC2D in the second cell tile T2D of the second cell MAT 110D may receive current from the second local Y-switches S24C of the first cell MAT 110C. The second memory cells MC2C in the second cell tile T2C of the first cell MAT 110C, the fourth memory cells MC4C in the fourth cell tile T4C of the first cell MAT 110C, and the second memory cells MC2D in the second cell tile T2D of the second cell MAT 110D may electrically share the second local Y-switches S24C of the first cell MAT 110C.

When the corresponding second local Y-switch S24D of the second cell MAT 110D is turned on, the corresponding memory cells MC4C in the fourth cell tile T4C of the first cell MAT 110C electrically connected through the corresponding Y-line YC4, the corresponding memory cells MC2D in the second cell tile T2D of the second cell MAT 110D electrically connected through the corresponding Y-line YD2, and the corresponding memory cells MC4D in the fourth cell tile T4D of the second cell MAT 110D electrically connected through the corresponding Y-line YD4 may be simultaneously selected and enabled. The fourth memory cells MC4C in the fourth cell tile T4C of the first cell MAT 110C, the second memory cells MC2D in the second cell tile T2D of the second cell MAT 110D, and the fourth memory cells MC4D in the fourth cell tile T4D of the second cell MAT 110D may receive current from the second local Y-switches S24D of the second cell MAT 110D. The fourth memory cells MC4C in the fourth cell tile T4C of the first cell MAT 110C, the second memory cells MC2D in the second cell tile T2D of the second cell MAT 110D, and the fourth memory cells MC4D in the fourth cell tile T4D of the second cell MAT 110D may electrically share the second local Y-switches S24D of the second cell MAT 110D.

When the corresponding second local Y-switch S24C of the first cell MAT 110C and the corresponding second local Y-switch S24D of the second cell MAT 110D electrically connected through the corresponding Y-lines YC4 and YD2 are simultaneously turned on, the corresponding memory cells MC2C MC4C, MC2D, and MC4D electrically connected through the corresponding Y-lines YC2, YC4, YD2, and YD4 may be simultaneously selected and enabled.

The memory cells MC3C, MC1D, MC4C, and MC2D in the cell tiles T3C, T1D, T4C, and T2D disposed to be adjacent to boundary regions (or edge regions) of the first cell MAT 110C and the second cell MAT 110D may simultaneously receive current from both switches S13C, S13D, S24C, and S2D. Therefore, in each of the cell tiles T3C, T1D, T4C, and T2D, the memory cells MC3C, MC1D, MC4C, and MC2D located far from both switches S13C, S24C, S13D, and S24D can receive sufficient current, can be stably selected, and can operate.

The local X-switch blocks S12C, S34C, S12D, and S34D and the X-lines XC12, XC34, XD12, and XD34 may be understood with reference to FIG. 1B.

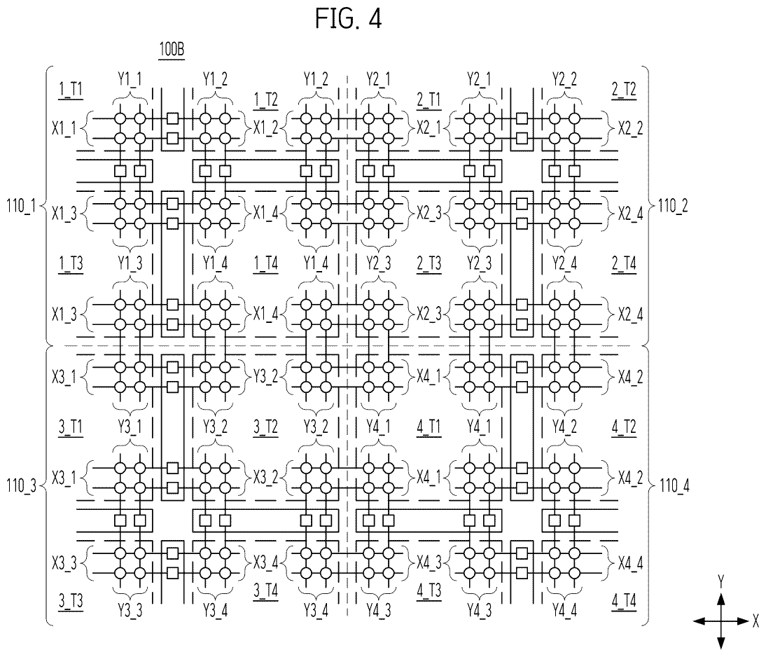

FIG. 4 is a diagram schematically illustrating a connection structure of X-lines (X1_1-X1_4, X2_1-X2_4, X3_1-X3_4, X4_1-X4_4) and Y-lines (Y1_1-Y1_4, Y2_1-Y2_4, Y3_1-Y3_4, and Y4_1-Y4_4) of cell MATs 110_1, 110_2, 110_3, and 110_4. In the first direction X, the first cell MAT 110_1 and the first cell MAT 110_2 may be disposed adjacent to each other on a first row, and the third cell MAT 110_3 and the fourth cell MAT 110_4 may be disposed adjacent to each other on a second row. In the second direction Y, the first cell MAT 110_1 and the third cell MAT 110_3 may be disposed adjacent to each other on a first column, and the second cell MAT 110_2 and the fourth cell MAT 110_4 may be disposed adjacent to each other on a second column.

Referring to FIG. 4, in the first direction X, the X-line X1_2 passing through the second cell tile 1_T2 of the first cell MAT 110_1 and the X-line X2_1 passing through the first cell tile 2_T1 of the second cell MAT 110_2 may be electrically connected to each other, the X-line X1_4 passing through the fourth cell tile 1_T4 of the first cell MAT 110_1 and the X-line X2_3 passing through the third cell tile 2_T3 of the second cell MAT 110_2 may be electrically connected to each other, the X-line X3_2 passing through the second cell tile 3_T2 of the third cell MAT 110_3 and the X-line X4_1 passing through the first cell tile 4_T1 of the fourth cell MAT 110_4 may be electrically connected to each other, and the X-line X3_4 passing through the fourth cell tile 3_T4 of the third cell MAT 110_3 and the X-line X4_3 passing through the third cell tile 4_T3 of the fourth cell MAT 110_4 may be electrically connected to each other.

In addition, the Y-line Y1_3 passing through the third cell tile 1_T3 of the first cell MAT 110_1 and the Y-line Y3_1 passing through the first cell tile 3_T1 of the third cell MAT 110_3 may be electrically connected, the Y-line Y1_4 passing through the fourth cell tile 1_T4 of the first cell MAT 110_1 and the Y-line Y3_2 passing through the second cell tile 3_T2 of the third cell MAT 110_3 may be electrically connected, the Y-line Y2_13 passing through the third cell tile 2_T3 of the second cell MAT 110_2 and the Y-line Y4_13 passing through the first cell tile 4_T1 of the fourth cell MAT 110_4 may be electrically connected, and the Y-line Y2_4 passing through the fourth cell tile 2_T4 of the second cell MAT 110_2 and the Y-line Y4_2 passing through the second cell tile 4_T2 of the fourth cell MAT 110_4 may be electrically connected.

An operation of the cell array 100 illustrated in FIG. 4 may be understood by referring to FIGS. 2 and 3. That is, the technical concepts described with reference to FIG. 2 and the technical concepts described with reference to FIG. 3 can be combined.

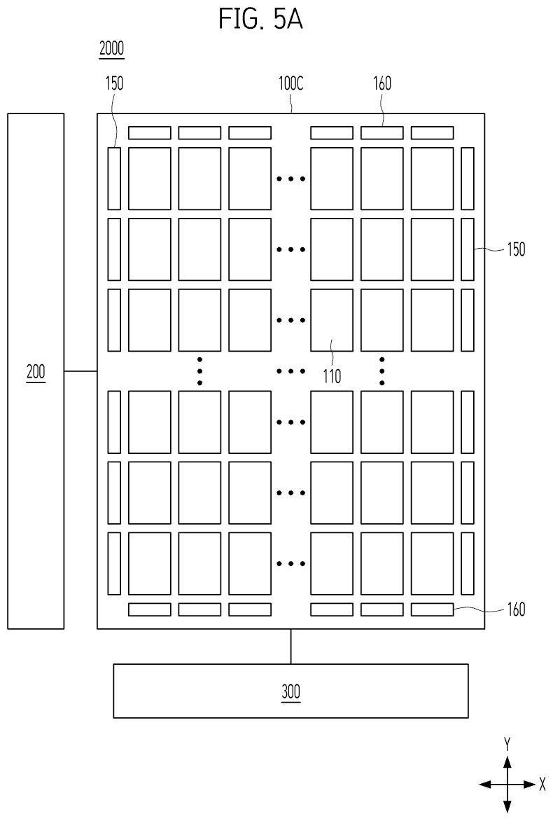

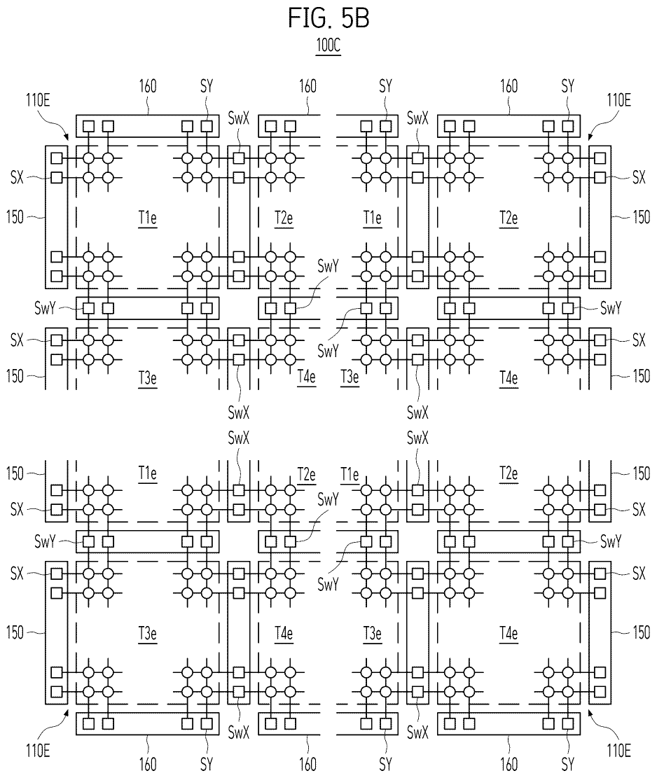

FIG. 5A is a block diagram of a semiconductor device 2000 according to an embodiment of the present disclosure, and FIG. 5B is a schematic enlarged diagram of cell MATs 110 located in edge regions of the cell array 100C of FIG. 5A.

Referring to FIGS. 5A and 5B, a semiconductor device 2000 may include a cell array 100C, an X-decoding block 200, a Y-decoding block 300, edge local X-switch blocks 150, and/or edge local Y-switch blocks 160. The edge local X-switch blocks 150 may be disposed adjacent to each edge of the edge cell MATs 110E located at the outermost edge in the first direction X of the cell array 100C. That is, each edge local X-switch block 150 may be symmetrically arranged to face each local X-switch block (similarly depicted as the edge local X-switch block 150 in FIG. 5B but not indicated by a reference numeral) with corresponding cell tiles T1e-T4e of each cell MAT 110E interposed therebetween. The edge local Y-switch blocks 160 may be disposed adjacent to each edge of the edge cell MATs 110E located at the outermost edge in the second direction Y of the cell array 100C. That is, each edge local Y-switch block 160 may be symmetrically arranged to face each local Y-switch block (similarly depicted as the edge local Y-switch block 160 in FIG. 5B but not indicated by a reference numeral) with corresponding cell tiles T1e-T4e of each cell MAT 110E interposed therebetween. The edge local X-switch blocks 150 may include edge local X-switches SX, and the edge local Y-switches SY may include edge local Y-switches SY. Thus, each the edge local X-switch SX may be symmetrically disposed with each the local X-switch (not denoted by a reference numeral) with the corresponding cell tiles T1e-T4e of each the cell MAT 110E interposed therebetween, and each the edge local Y-switch SY may be disposed symmetrically with each the local X-switch (not denoted by a reference numeral) with the corresponding cell tiles T1e-T4e of each the cell MAT 110E interposed therebetween.

Each the edge local X-switch SX may be turned on simultaneously with a corresponding one of the edge local X-switches SwX in the edge cell MATs 110E to provide a current to edge X-lines (not indicated by a reference numeral) in the outermost edge cell tiles T1e-T4e in the edge cell MATs 110E. Each edge local Y-switch SY may be turned on simultaneously with a corresponding one of the edge local Y-switches SwY in the edge cell MATs 110E to provide a current to edge Y-lines (not indicated by a reference numeral) in the outermost edge cell tiles T1e-T4e in the edge cell MATs 110E. Accordingly, the edge X-lines (not indicated by a reference numeral) and/or the edge Y-lines (not denoted by a reference numeral) in the outermost edge cell tiles T1e-T4e may receive current from both edge switches (edge local X-switches SwX and SX (and/or edge local Y-switches SwY and SY)).

According to embodiments of the present disclosure, sufficient current can be supplied to all memory cells MC in the cell MATs 110 and 110A-110E and 110_1-110_4. Therefore, the semiconductor devices 1000 and 2000 can operate stably. Also, since the current transfer capability can be improved, areas of the cell MATs 110, 110A-110E, and 110_1-110_4 can be set to be larger. That is, more memory cells MC can be disposed in the cell tiles T1 to T4, and the degree of integration and area efficiency of the semiconductor device 1000 can be improved.

The technical concepts described with reference to FIGS. 2 to 4 and the technical concepts described with reference to FIG. 5 can be combined.

According to the embodiments of the present disclosure, each memory cell can receive current from two local switches disposed on both sides. Therefore, selection or enablement of the memory cell can be stably performed.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A semiconductor device comprising:
a cell array including a first cell MAT and a second cell MAT adjacent to each other in a first direction,
wherein the first cell MAT includes:
first to fourth cell tiles arranged in a matrix form;
a first local X-switch disposed between the first cell tile and the second cell tile;
a first X-line extending from the first local X-switch to pass through the first cell tile in the first direction; and
a second X-line extending from the first local X-switch to pass through the second cell tile in the first direction,
wherein the second cell MAT includes:
first to fourth cell tiles arranged in a matrix form;
a first local X-switch disposed between the first cell tile and the second cell tile;
a first X-line extending from the first local X-switch to pass through the first cell tile in the first direction; and
a second X-line extending from the first local X-switch to pass through the second cell tile in the first direction,
wherein the first local X-switch of the first cell MAT is electrically shared with the first X-line of the first cell MAT, the second X-line of the first cell MAT, and the first X-line of the second cell MAT, and
wherein the first local X-switch of the second cell MAT is electrically shared with the second X-line of the first cell MAT, the first X-line of the second cell MAT, and the second X-line of the second cell MAT.

2. The semiconductor device of claim 1,
wherein the first cell MAT further includes:
a second local X-switch disposed between the third cell tile and the fourth cell tile;
a third X-line extending from the second local X-switch to pass through the third cell tile in the first direction; and
a fourth X-line extending from the second local X-switch to pass through the fourth cell tile in the first direction,
wherein the second cell MAT further includes:
a second local X-switch disposed between the third cell tile and the fourth cell tile;
a third X-line extending from the second local X-switch to pass through the third cell tile in the first direction; and
a fourth X-line extending from the second local X-switch to pass through the fourth cell tile in the first direction,
wherein the second local X-switch of the first cell MAT is electrically shared with the third X-line of the first cell MAT, the fourth X-line of the first cell MAT, and the third X-line of the second cell MAT, and
wherein the second local X-switch of the second cell MAT is electrically shared with the fourth X-line of the first cell MAT, the third X-line of the second cell MAT, and the fourth X-line of the second cell MAT.

3. The semiconductor device of claim 2, further comprising:
a third cell MAT adjacent to the first cell MAT in a second direction perpendicular to the first direction,
wherein the third cell MAT includes first to fourth cell tiles arranged in a matrix form,
wherein the first cell MAT includes:
a first local Y-switch between the first cell tile and the third cell tile;
a second local Y-switch between the second cell tile and the fourth cell tile;
a first Y-line extending from the first local Y-switch to pass through the first cell tile in the second direction;
a second Y-line extending from the second local Y-switch to pass through the second cell tile in the second direction;
a third Y-line extending from the first local Y-switch to pass through the third cell tile in the second direction; and
a fourth Y-line extending from the second local Y-switch to pass through the fourth cell tile in the second direction,
wherein the third cell MAT includes:
a first local Y-switch between the first cell tile and the third cell tile;
a second local Y-switch between the second cell tile and the fourth cell tile;
a first Y-line extending from the first local Y-switch to pass through the first cell tile in the second direction;
a second Y-line extending from the second local Y-switch to pass through the second cell tile in the second direction;
a third Y-line extending from the first local Y-switch to pass through the third cell tile in the second direction; and
a fourth Y-line extending from the second local Y-switch to pass through the fourth cell tile in the second direction,
wherein the first local Y-switch of the first cell MAT is electrically shared with the first Y-line of the first cell MAT, the third Y-line of the first cell MAT, and the first Y-line of the third cell MAT, and
wherein the first local Y-switch of the third cell MAT is electrically shared with the third Y-line of the first cell MAT, the first Y-line of the third cell MAT, and the third Y-line of the third cell MAT.

4. The semiconductor device of claim 3,
wherein the second local Y-switch of the first cell MAT is electrically shared with the second Y-line of the first cell MAT, the fourth Y-line of the first cell MAT, and the second Y-line of the third cell MAT, and
wherein the second local Y-switch of the third cell MAT is electrically shared with the fourth Y-line of the first cell MAT, the second Y-line of the third cell MAT, and the fourth Y-line of the third cell MAT.

5. The semiconductor device of claim 3,
wherein the first cell MAT further comprises:
a first edge local Y-switch adjacent to an edge area of the first cell tile of the first cell MAT in the second direction; and
a second edge local Y-switch adjacent to an edge area of the second cell tile of the first cell MAT in the second direction,
wherein the first edge local Y-switch of the first cell MAT provides a current to memory cells in the first cell tile of the first cell MAT, and
wherein the second edge local Y-switch of the first cell MAT provides a current to memory cells in the second cell tile of the first cell MAT.

6. The semiconductor device of claim 5,
wherein the second cell MAT further comprises:
a first edge local Y-switch adjacent to an edge area of the first cell tile of the second cell MAT in the second direction; and
a second edge local Y-switch adjacent to an edge area of the second cell tile of the second cell MAT in the second direction,
wherein the first edge local Y-switch of the second cell MAT provides a current to memory cells in the first cell tile of the second cell MAT, and
wherein the second edge local Y-switch of the second cell MAT provides a current to memory cells in the second cell tile of the second cell MAT.

7. The semiconductor device of claim 3,
wherein the first cell MAT further comprises:
a first edge local X-switch adjacent to an edge area of the first cell tile of the first cell MAT in the first direction; and
a second edge local X-switch adjacent to an edge area of the third cell tile of the first cell MAT in the first direction,
wherein the first edge local X-switch of the first cell MAT provides a current to memory cells of the first cell tile of the first cell MAT, and
wherein the second edge local X-switch of the first cell MAT provides a current to memory cells of the third cell tile of the first cell MAT.

8. The semiconductor device of claim 7,
wherein the third cell MAT further comprises:
a first local X-switch disposed between the first cell tile and the second cell tile;
a second local X-switch disposed between the third cell tile and the fourth cell tile;
a first edge local X-switch adjacent to the first cell tile in the first direction;
a second edge local X-switch adjacent to the third cell tile in the first direction;
a first X-line extending from the first local X-switch to pass through the first cell tile in the first direction and electrically connected to the first edge local X-switch;
a second X-line extending from the first local X-switch to pass through the second cell tile in the first direction;
a third X-line extending from the second local X-switch to pass through the third cell tile in the first direction and electrically connected to the second edge local X-switch; and
a fourth X-line extending from the second local X-switch to pass through the fourth cell tile in the first direction.

9. The semiconductor device of claim 3,
wherein each of the first to fourth cell tiles of each of the first to third cell MATs comprises:
a plurality of memory cells arranged in a matrix form,
wherein each of the plurality of memory cells is disposed on an intersection of the first X-line and the first Y-line, an intersection of the second X-line and the second Y-line, an intersection of the third X-line and the third Y-line, and an intersection of the fourth X-line and the fourth Y-line.

10. The semiconductor device of claim 1, further comprising:
an X-decoding block adjacent to the cell array in the first direction; and
a Y-decoding block adjacent to the cell array in a second direction perpendicular to the first direction,
wherein the X-decoding block includes an address coding circuit, and
wherein the Y-decoding block includes a global Y-switching circuit and a sense amplifier circuit.

11. A semiconductor device comprising:
a cell array having first to fourth cell MATs,
wherein each of the first to fourth cell MATs includes:
first to fourth cell tiles arranged in a matrix form;
a first local X-switch disposed between the first cell tile and the second cell tile;
a second local X-switch disposed between the third cell tile and the fourth cell tile;
a first local Y-switch disposed between the first cell tile and the third cell tile;
a second local Y-switch disposed between the second cell tile and the fourth cell tile;
a first Y-line extending from the first local Y-switch to pass through the first cell tile;
a second Y-line extending from the second local Y-switch to pass through the second cell tile;
a third Y-line extending from the first local Y-switch to pass through the third cell tile; and
a fourth Y-line extending from the second local X-switch to pass through the fourth cell tile,
wherein the first local Y-switch of the first cell MAT is electrically shared with the first Y-line of the first cell MAT, the third Y-line of the first cell MAT, and the first Y-line of the third cell MAT.

12. The semiconductor device of claim 11,
wherein the first local Y-switch of the third cell MAT is electrically shared with the third Y-line of the first cell MAT, the first Y-line of the third cell MAT, and the third Y-line of the third cell MAT.

13. The semiconductor device of claim 11,
wherein the second local Y-switch of the first cell MAT is electrically shared with the second Y-line of the first cell MAT, the fourth Y-line of the first cell MAT, and the second Y-line of the third cell MAT.

14. The semiconductor device of claim 13,
wherein the second local Y-switch of the third cell MAT is electrically shared with the fourth Y-line of the first cell MAT, the second Y-line of the third cell MAT, and the fourth Y-line of the third cell MAT.

15. The semiconductor device of claim 11,
wherein the first cell MAT and the second cell MAT are adjacent to each other in a first direction, and the third cell MAT and the fourth cell MAT are adjacent to each other in the first direction,
wherein the first cell MAT and the third cell MAT are adjacent to each other in a second direction, and the second cell MAT and the fourth cell MAT are adjacent to each other in the second direction, and
wherein the first direction and the second direction are perpendicular to each other.

16. The semiconductor device of claim 15,
wherein the first cell tile and the second cell tile are adjacent to each other in the first direction, and the third cell tile and the fourth cell tile are adjacent to each other in the first direction, and
wherein the first cell tile and the third cell tile are adjacent to each other in the second direction, and the second cell tile and the fourth cell tile are adjacent to each other in the second direction.

17. A semiconductor device comprising:
a cell array including a first cell MAT and a second cell MAT adjacent to each other,
wherein each of the first cell MAT and the second cell MAT includes:
first to fourth cell tiles arranged in a matrix form with a first direction and a second direction perpendicular to each other;
a first local Y-switch disposed between the first cell tile and the third cell tile;
a second local Y-switch disposed between the second cell tile and the fourth cell tile;
a first Y-line extending from the first local Y-switch to pass through the first cell tile in the second direction;
a second Y-line extending from the second local switch to pass through the second cell tile;
a third Y-line extending from the first local Y-switch to pass through the third cell tile in the second direction; and
a fourth Y-line extending from the second local switch to pass through the fourth cell tile,
wherein the first local Y-switch of the first cell MAT is electrically shared with the first Y-line of the first cell MAT, the third Y-line of the first cell MAT, and the first Y-line of the second cell MAT.

18. The semiconductor device of claim 17,
wherein the first local Y-switch of the second cell MAT is electrically shared with the third Y-line of the first cell MAT, the first Y-line of the second cell MAT, and the third Y-line of the second cell MAT.

19. The semiconductor device of claim 17,
wherein the second local Y-switch is electrically shared with the second Y-line of the first cell MAT, the fourth Y-line of the first cell MAT, and the second Y-line of the second cell MAT.

20. The semiconductor device of claim 19,
wherein the second local Y-switch is electrically shared with the fourth Y-line of the first cell MAT, the second Y-line of the second cell MAT, and the fourth Y-line of the second cell MAT.
